(19) United States
(12) Patent Application Publication
(10) Pub. No.: US 2023/0189424 A1
(43) Pub. Date: Jun. 15, 2023

(54) EMITTER AND METHOD FOR PLASMA FUSING OF MATERIALS

(71) Applicant: Essentium IPCo, LLC, Pflugerville, TX (US)

(72) Inventors: William Jack MacNeish, III, Santa Ana, CA (US); Charles Brandon Sweeney, Pflugerville, TX (US); Blake Teipel, Pflugerville, TX (US)

(21) Appl. No.: 17/997,593

(22) PCT Filed: Apr. 30, 2021
(86) PCT No.: PCT/US21/30075

§ 371 Date: Oct. 31, 2022

Related U.S. Application Data
(60) Provisional application No. 63/018,901, filed on May 1, 2020.

(51) Int. Cl. H05H 1/34; H01J 37/32; H01L 21/67

(52) U.S. Cl. CPC H05H 1/34; H01J 37/32348; H01J 37/3244; H01L 21/67126; H01J 2237/2007; H01J 2237/20278

(57) ABSTRACT

An emitter and process for plasma fusing of materials. The emitter including a discharge device defining an emitter or an emitter array configured to create a directed plasma to transfer energy to a target object; and a plasma generating electrical system including a power source and two poles, wherein one of said two poles is connected to the target object and the other of said two poles is connected to the discharge device.

### CROSS-REFERENCE TO RELATED APPLICATIONS

The present application is a national stage of International Application No.: PCT/US21/30075, filed on Apr. 30, 2021, which claims the benefit of U.S. Provisional Application No. 63/018,901, filed on May 1, 2020, the teachings of which are incorporated herein by reference.

### FIELD

The present disclosure relates to an apparatus and methods for producing three dimensional printed parts.

### BACKGROUND

Three-Dimensional Printing or Additive Manufacturing represents several processes for creating three dimensional objects from a digital computer aided design CAD design model. A three-dimensional printed part is formed by stacking, or depositing, several two-dimensional layers of material such that the end result is an object having length, width, and height. In several of the processes, materials used to form the objects can range from metal to thermoplastic and composite. These processes are capable of producing intricate parts having great detail, however the current processes require substantial time to produce large three-dimensional printed parts particularly when a laser is used to locally sinter portions of a powder layer such as a selective laser sintering (SLS) method.

Some process improvements include attempts to increase the cohesive strength between the layers of the three-dimensional printed object. These attempts include in-process and post-process steps that involve different methods of heating the printed object such that the layers soften or even melt to promote cross-solidification or crystallization between the layers. Other processes produce individual/layers of material by depositing a powder material followed by application of a mask and a laser scan over the powder and masked layer to sinter the powder layer. Multiple processes have also been developed to fuse feedstock materials into a finished-shape part, including Newtonian conduction, convective sintering and chemo-irradiative coupling. Laser processes are time consuming due to the small size of the laser contact area and the time required to track the laser over an entire surface of the component. For example, known laser processes require approximately 10 to 20 seconds to fuse an area of approximately 100 cm².

While current three-dimensional printers and processes achieve their intended purpose, there is a need for an improved three-dimensional printer and process for providing parts for an increasing array of applications requiring improved strength, dimensional capability, and multi-functional purposes.

### SUMMARY

According to several aspects, a process and an emitter for plasma fusing of materials includes a discharge device defining an emitter or an emitter array creating a directed plasma of controlled intensity used to transfer energy to a target object.

In another aspect of the present disclosure, a ratio of the extents of the discharge device to a gap between the discharge device and the target object is maintained very large, and therefore an emitter diameter or surface area of the emitter is greater than the gap between the discharge device and the target object.

In another aspect of the present disclosure, the discharge device provides the target object in powder form applied directly onto the discharge device, with the discharge device moved proximate to an applicator allowing the plasma to pass through the target object, sintering or fusing the material of the target object.

In another aspect of the present disclosure, the discharge device is moved into direct contact with an applicator allowing the plasma to be generated directly through the target object, sintering or fusing the material of the target object.

In another aspect of the present disclosure, a material of the target object is conductive and is connected to one pole of a plasma-generating electrical system.

In another aspect of the present disclosure, a geometry of the target object is imaged” into a desired geometry, and the discharge device is moved proximate to the target object on a device-under-build (DUB) and fired or energized by a power source.

In another aspect of the present disclosure, the emitter defines a surface dielectric barrier discharge device (SDBD) creating the directed plasma of controlled intensity used to transfer energy to the target object.

In another aspect of the present disclosure, the SDBD comprises a silicon wafer having an array of cathode pads and anode pads on a surface of the SDBD, the array of cathode pads and anode pads covered with a layer of material having a high dielectric constant defining the target object.

In another aspect of the present disclosure, a geometry of the target object is achieved by selectively energizing portions of the discharge device or by operating the discharge device in multiple successive shots of applied energy to melt or sinter a powder which creates the target object.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a top perspective view of a process and an emitter for plasma fusing of materials according to an exemplary aspect;

FIG. 2 is a side elevational cross-sectional view of another aspect;

FIG. 3 is a side elevational view of another aspect;

FIG. 4 is a side elevational view of the aspect of FIG. 4 following deflection to release a fused, target object;

FIG. 5 is a top perspective view similar to FIG. 1 showing another aspect of the process and emitter for plasma fusing of materials of the present disclosure; and

FIG. 6A is a schematic of an embodiment of an additive manufacturing system;

FIG. 6B is a bottom perspective view of an embodiment of an emitter; and

FIG. 6C is a bottom perspective view of an emitter.

### DETAILED DESCRIPTION

The following description is merely exemplary in nature and is not intended to limit the present disclosure, application, or uses.

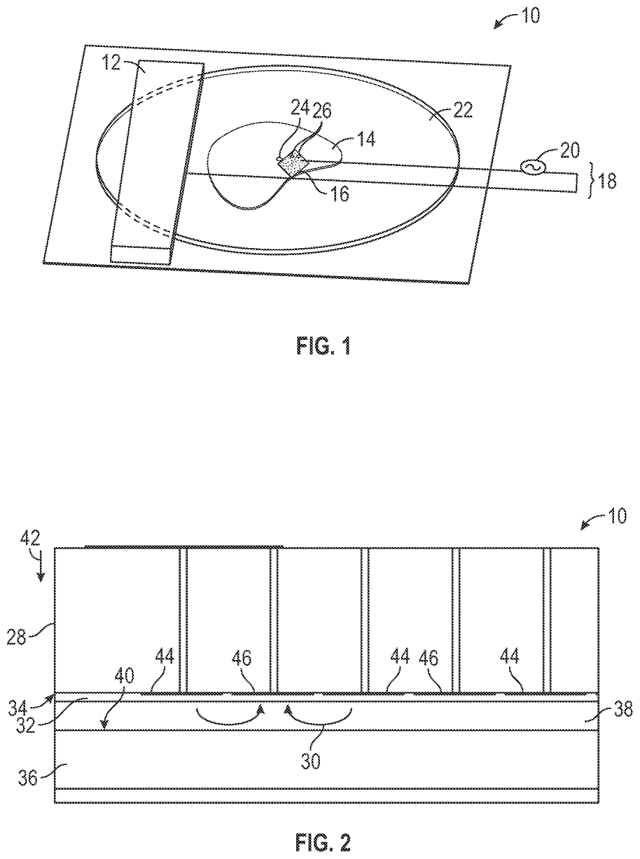

Referring to FIG. 1, a process and an emitter for plasma fusing of materials 10 includes a discharge device 12 defining an emitter or an emitter array creating a directed plasma 14 of controlled intensity used to transfer energy to a target object 16. The target object 16 is understood herein as the object to which the energy from the emitter is directed. The energy is of sufficient power and density to affect the target object 16 in the manner discussed herein. According to several aspects, a ratio of the extents of, or the area covered by, the discharge device 12, emitter, or emitter array to a gap between the discharge device 12 and the target object 16 is maintained very large, and therefore an emitter diameter or surface area of the emitter is greater than the gap. In aspects, the ratio of the extents to the gap is greater than 1 to 1, and in further aspects, greater than 10 to 1.

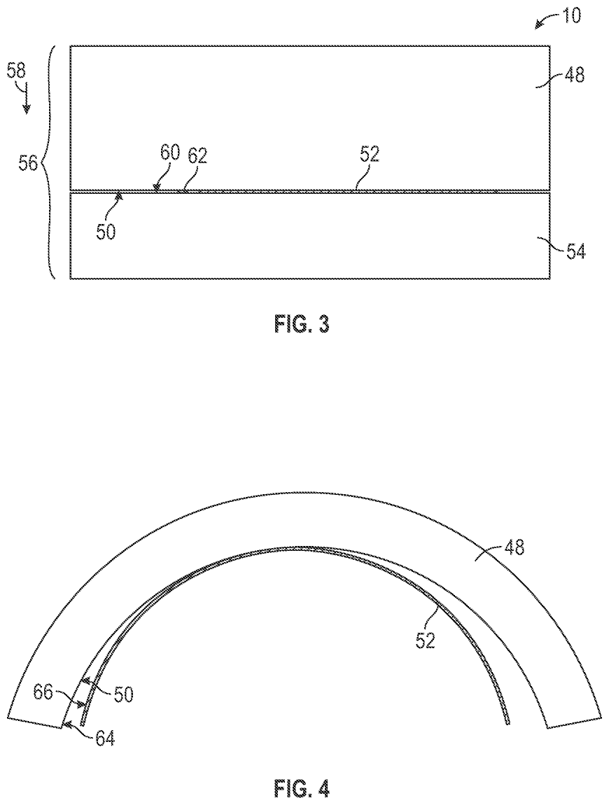

According to several aspects, a discharge device may have the target object, for example in powder form, applied directly onto the discharge device, with the discharge device moved proximate to an applicator shown and described in reference to FIG. 2, which allows the plasma to pass through the target object, sintering or fusing the material of the target object. According to other aspects, a discharge device is moved into direct contact with an applicator as shown and described in reference to FIG. 3, which allows a plasma to be generated directly through a target object, sintering or fusing the material of the target object.

With continuing reference to FIG. 1, one element of the deployment of the plasma 14 provides for a material of the target object 16 to be conductive and connected to one pole of a plasma-generating electrical system 18 having a power source 20. The power source 20 is also connected to the discharge device 12. The target object 16 may combine one or more of all of the following: a powder, a film (alpha, beta, or cured stage), a resin, siloxanes, and a deposited material defining a fused filament fabrication (FFF material). The powder, resin and deposited material may be formed from one or more of a thermoplastic, metal and ceramic.

According to several aspects, the target object 16, for example in the form of a polymeric material powder is initially applied to a device-under-build (DUB) 22. According to several aspects, a geometry of the target object 16 is “imaged” into a desired geometry. The discharge device 12 is then moved into a position proximate to the target object 16 on the device-under-build (DUB) 22 and “fired” or energized by the power source 20. When charged to a different potential, the plasma 14 is generated between the discharge device 12 and the DUB 22, which heats and fuses the material of the target object 16 to the device-under-build (DUB) 22 using as few as a single shot of energy from the discharge device 12 applied over an entire area of the target object 16. According to further aspects, multiple successive shots of energy and therefore multiple applications of the plasma 14 may be applied to achieve the desired geometry of the target object 16.

A pattern or image of the target object 16 may be predetermined before or during application of the plasma 14 and may be selected from multiple image portions which together define a finished or desired pattern. One or multiple images or patterns defining the target object 16 may be saved in a memory which may be generated for example by an image slicer known in the art and therefore applied in one or more layers by sintering the single layer or by successively sintering multiple layers of material. According to several aspects, a desired geometry of the target object 16 may also be achieved by selectively energizing portions of the discharge device 12 or by operating the discharge device 12 in multiple successive shots of applied energy to melt or sinter the powder which creates the target object 16. According to several aspects, individual pixels 24 created in the target object 16 may have an individual pixel brightness increased or decreased with respect to adjacent ones of multiple pixels 26 by modifying local power levels at the individual pixels 24 delivered by the discharge device 12.

Referring to FIG. 2 and again to FIG. 1, according to several aspects, the process and the emitter for plasma fusing of materials 10 may include a surface dielectric barrier discharge device (SDBD) 28 defining an emitter creating a directed plasma 30 of controlled intensity used to transfer energy to a target object 32. The target object 32 is a dielectric material defining an electrical insulator that can be polarized by an applied electric field. The target object 32 may be applied or scraped directly onto a surface 34 of the SDBD 28. The plasma 30 is deployed or “fired” as a controlled energy source after bringing the SDBD 28 into close proximity with an applicator 36, thereby creating a gap 38 having a predetermined spacing with respect to a surface 40 of the applicator 36 in a direction 42 such as but not limited to an exemplary downward direction shown. A pattern or image of the target object 32 is predetermined and may be selected from multiple patterns which together define a finished or desired pattern generated for example as one or multiple ones of the target objects 32 saved in a memory after generation for example by an image slicer known in the art.

According to several aspects, the SDBD 28 may comprise a silicon wafer having an array of cathode pads 44 and anode pads 46 on the surface 34 of the SDBD 28. The SDBD 28 may be similar to a wafer used for integrated circuit boards, having the array of cathode pads 44 and anode pads 46 on the surface 34 covered with a layer of material having a high dielectric constant defining a target object 32. Both poles for plasma generation are therefore positioned on the SDBD 28 or plasma applicator, eliminating the need for the target object 32 to be conductive and to act as a conductive pole. When adjoining or successive ones of the cathode pads 44 and the anode pads 46 are thereafter charged to a different potential the plasma 30 generates as an arc in an ambient medium of the gap 38. The ambient medium may be air, argon, hydrogen or other medium material between the adjoining ones of the cathode pads 44 and anode pads 46 and the applicator 36. The plasma 30 fuses the target object 32 to the SDBD 28 in the predetermined pattern.

Referring to FIG. 3 and again to FIG. 1, according to further aspects, an emitter 48 has a material similar to the target object 16 applied to a first surface 50 of the emitter 48 defining a target object 52. The target object 52 may be applied or scraped directly onto the first surface 50 of the emitter 48. The emitter 48 and an applicator 54 together define an emitter assembly 56. During operation the emitter 48 is moved in an exemplary downward direction 58 and positioned with the first surface 50 of the emitter 48 and the material of the target object 52 in direct contact with a second surface 60 of the applicator 54. When the facing and adjoining first surface 50 and the second surface 60 are charged to a predetermined degree of different electrical potential, a plasma arc 62 extends through the layer of the target object 52, heating and fusing the target object 52 to the emitter 48.

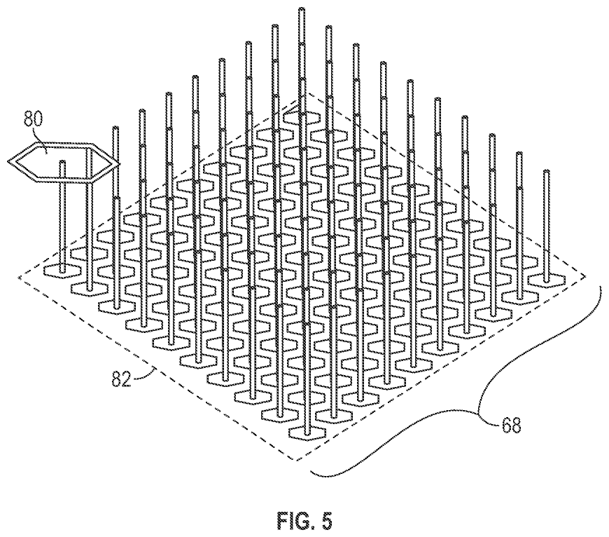

Referring to FIG. 4 and again to FIGS. 1 through 3, with particular reference to the aspects of FIG. 3, when the material of the target object 52 under the emitter 48 fuses, it may adhere or stick to the dielectric layer on the first surface 50 of the emitter 48. To remove material from the dielectric layer at the first surface 50 the emitter 48 may be designed to be “flexible”, allowing the emitter 48 to be bent or deflected, hereinafter referred to as deflected. Deflecting the emitter 48 allows edges 64 of the emitter 48 to be “cracked” first, followed by release of the edges 64 of the emitter 48 from an outer surface 66 of the target object 52, thereby allowing removal of the entire emitter 48 from the now fused layer defining the target object 52.

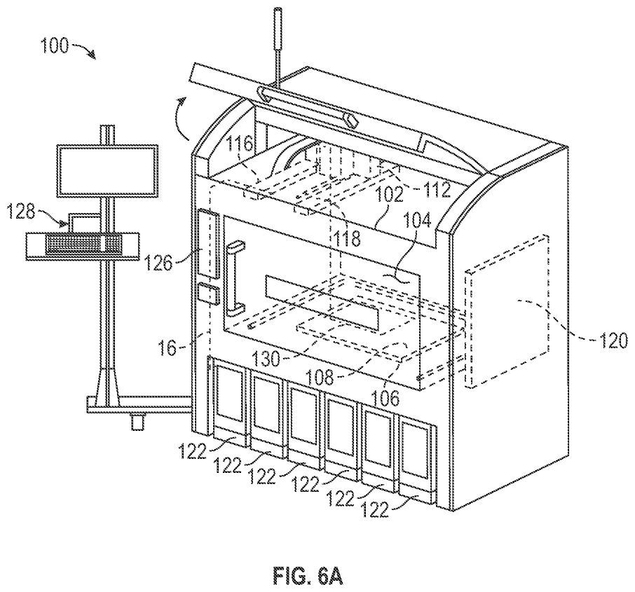

Referring to FIG. 5 and again to FIGS. 1 through 3, the emitters of the present disclosure may provide a linear array of plasma that is swept across an area of interest. The emitters of the present disclosure may therefore provide a 2D array of plasma generators that are fired in a spatial pattern 68 or in a sequence of patterns.

Plasma generated using any of the emitter aspects of the present disclosure may be used to de-bind low-energy-content polymers from a metal target material composite. Plasma generated using any of the emitter aspects of the present disclosure may also be used to provide energy to fully fuse materials, as opposed to de-binding polymers and other materials. A plasma-generating emitter of the present disclosure may further be used to fuse pre-imaged polymeric powder or polymeric film layers of one or more polymers to a device-under-build (DUB).

The plasma emitters of the present disclosure including the aspects described above with respect to FIG. 3 additionally act as a mechanical leveler or coiner of a polymeric powder layer during contact and before and during the fusing process. This is applicable whether the plasma emitter is a DBD or an SDBD arrangement. The emitters of the present disclosure also “self-level” so that plasma density is uniform across a fusing area.

As the plasma-emitting surface of the emitter having a layer of powder/film/FFF material as the target object is heated and fused with plasma energy, the material of the target object dielectric constant and other properties will change. A control system is therefore implemented that senses these changes and adapts to them. According to several aspects, in an exemplary aspect the control system monitors voltage and current through a plasma generator electronics package to observe loading and coupling of a stream of the plasma relative to the target object.

The emitters of the present disclosure may comprise many small plasma cells 80 defining an image array to control uniformity, and to image/shape a fusing area 82. The emitters may also be operated to electrostatically image raw polymeric powder prior to conducting the coining and fusing operations.

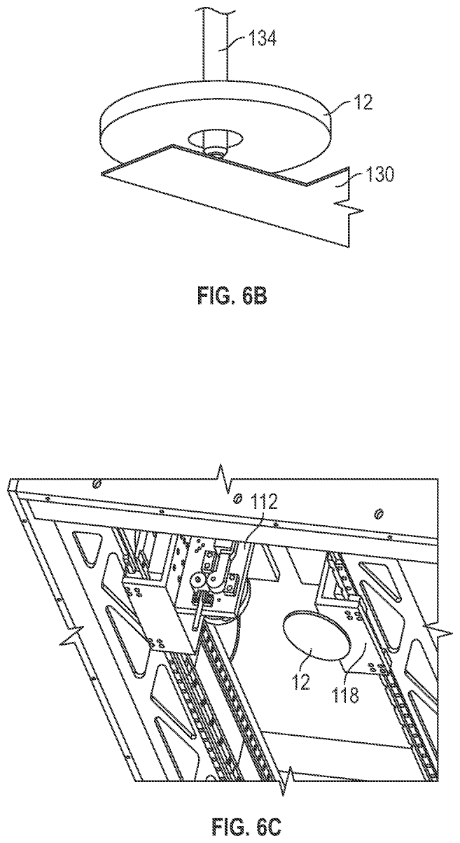

In aspects, and with reference to FIG. 6A, the emitter 12 is mounted in an additive manufacturing system 100, such as a three-dimensional printer for application of the directed plasma 14 during or after printing. The additive manufacturing system 100 includes an enclosure 102 defining a process chamber 104 and a support bed 106 including a build surface 108 supported within the process chamber 104. The additive manufacturing system 100 further includes an applicator head 112, in this aspect a print head, on an x,y-gantry 116 and moveable in an x,y-plane. The support bed 106 is moved relative to the applicator head 112 by a z-axis gantry 120. The target object 16, in this case a filament, is stored in one or more canisters 122 and provided to an applicator head 112 by a filament drive system 126. A controller 128 is provided to control the various functions of the three-dimensional printer. In alternative aspects, the support bed 106 may hold the target object 16, such as powder, film, or resins described above, which target object 16 is applied by an applicator 36 in the applicator head 112. The target object 16 is deposited on and disposed on the support bed 106 and formed into a three-dimensional object 130.

FIG. 6B illustrates the mounting of a discharge device 12 within the process chamber 104 around the extrusion nozzle 134 connected to an applicator head 112 in a three-dimensional printer. FIG. 6C illustrates an alternative aspect including the mounting of the discharge device 12 in the process chamber 104 to a secondary x,y-gantry 118 and follows the applicator head 112. Where the additive manufacturing system is a fused filament fabrication system, the discharge device 12 follows after the extrusion nozzle 134. Further, the motion of the emitter 12 may be adjusted to concentrate energy on recently-deposited material.

In aspects of the processes described above, the process chamber 104 may exhibit a controlled atmosphere, wherein vacuum is applied to the atmosphere during the processes described above. In addition to the application of vacuum, or alternatively to the application of vacuum, a gas may be supplied to the process chamber, such as argon, helium, and hydrogen.

In aspects, the controller 128 is used to provide a power supply and regulate the power to the discharge device 12. The controller 128 also includes executable code to control the plasma energy discharged by the discharge device in synchronization with the fusing process using voltage-current sensing. In aspects, the controller 128 also includes executable code to select and charge specific cells 80 of the discharge device.

In particular aspects, the process of fusing the target object of the present disclosure may occur in approximately 100 ms for a 300×300×0.2 mm volume of material in a 3D printing machine. Having the layers fused allows the layers to be imaged/shaped in parallel with the fusing process, providing a throughput of approximately 1 kg per minute, compared to current 3D printing technologies which average approximately 1 kg per hour. A spatially and temporally managed plasma field of the present disclosure may be used to de-bind some materials and areas, fuse other materials and areas, and remove or vaporize other materials and areas.

A process and an emitter for plasma fusing of materials 10 of the present disclosure offers several advantages. These include fusing raw material layers with a plasma field, fusing deposited, but un-fused FFF layers—polymer, metal or ceramic material. The process and an emitter for plasma fusing of materials 10 of the present disclosure provides an SDBD approach to plasma generation/management, mechanically coins layers in conjunction with fusing, fuses films with a certain, known dielectric constant, and uses V/I sensing to control plasma energy in synchronization with the fusing process.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. An emitter for plasma fusing of materials, comprising:
a discharge device defining an emitter or an emitter array configured to create a directed plasma to transfer energy to a target object; and
a plasma generating electrical system including a power source and two poles, wherein one of said two poles is connected to the target object and the other of said two poles is connected to the discharge device.

2. The emitter of claim 1, wherein a ratio of extents of the discharge device to a gap between the discharge device and the target object is greater than 1 to 1.

3. The emitter of claim 1, further comprising an applicator.

4. The emitter of claim 3, wherein the discharge device directly contacts the applicator allowing the plasma to be generated directly through the target object.

5. The emitter of claim 1, wherein a material of the target object is conductive and is connected to one pole of a plasma-generating electrical system.

6. The emitter of claim 1, wherein the discharge device is proximate to the target object on a device-under-build (DUB).

7. The emitter of claim 1, wherein the emitter defines a surface dielectric barrier discharge device (SDBD).

8. The emitter of claim 7, wherein the SDBD comprises a silicon wafer having an array of cathode pads and anode pads on a surface of the SDBD, the array of cathode pads and anode pads covered with a layer of material having a high dielectric constant defining the target object.

9. An additive manufacturing system, comprising:
a support bed, including a build surface;
an applicator head; wherein the support bed is moveable relative to the applicator head; and
a discharge device, mounted over the support bed.

10. The additive manufacturing system of claim 9, wherein a target object is disposed on the support bed.

11. The additive manufacturing system of claim 9, wherein the applicator head is mounted on a first gantry and the discharge device is mount on a second gantry.

12. A process for plasma fusing of a target object, comprising:
disposing a target object on a support bed with an applicator;
discharging plasma from a plasma discharge device defining an emitter or an emitter array; and
altering the target object with the discharged plasma.

13. The process of claim 12, wherein altering the target object comprises fusing the target object to a device under build.

14. The process of claim 12, wherein the target object comprises a polymer material and altering the target object further comprises de-binding the target object from an other material.

15. The process of claim 12, wherein the other material comprises metal.

16. The process of claim 12, wherein the target object comprises a vaporizable material and altering the target object further comprises vaporizing the target object.

17. The process of claim 12, wherein the applicator provides the target object in powder form and the target object is applied directly onto the discharge device.

18. The process of claim 17, further comprising:
moving the discharge device proximate to the applicator allowing the plasma to pass through the target object; and
fusing the target object.

19. The process of claim 12, wherein a material of the target object is conductive and is connected to one pole of a plasma-generating electrical system.

20. The process of claim 12, further comprising:
moving the discharge device proximate to the target object on a device-under-build (DUB); and
firing a power source, wherein a geometry of the target object is imaged into a desired geometry.

21. The process of claim 12, further comprising selectively energizing portions of the discharge device.

22. The process of claim 12, further comprising discharging the plasma in multiple successive shots of applied energy to the target object.
